(19) United States
(12) Patent Application Publication
(10) Pub. No.: US 2010/0050769 A1
(43) Pub. Date: Mar. 4, 2010

(54) ANGULAR VELOCITY SENSOR

(75) Inventors: Kosuke Watanabe, Takaoka-shi (JP); Keiichi Okano, Toyama-shi (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi (JP)

(21) Appl. No.: 12/539,841

(22) Filed: Aug. 12, 2009

(30) Foreign Application Priority Data
Sep. 2, 2008 (JP) 2008-224566

(51) Int. Cl. G01C 19/56; H01L 41/04

(52) U.S. Cl. 73/504.16; 310/370

(57) ABSTRACT

An angular velocity sensor includes vibrators, an internal circuit that drives the vibrators to detect an angular velocity signal, a circuit substrate on which components such as an IC and a passive component defining the internal circuit are disposed, and electrically connects the vibrators and the components, and a cap that covers a surface of the circuit substrate and encloses the vibrators and internal circuit. An output signal processed by the internal circuit is output from an external electrode provided on the back surface of the circuit substrate. Vibrator inspection electrodes are provided on the back surface of the circuit substrate, and the vibrator inspection electrodes are electrically connected to surface electrodes of the vibrators. Thus, electrical characteristics of the vibrators can be directly measured after assembly.

### BACKGROUND OF THE INVENTION

1. Field of the Invention

The present invention relates to an angular velocity sensor that detects a rotation angular velocity, and in particular, an angular velocity sensor for use in, for example, a hand-motion detector for a camera and a car navigation system.

2. Description of the Related Art

A known angular velocity sensor is described in Japanese Unexamined Patent Application Publication No. 2005-257615. This angular velocity sensor includes a vibrator, an internal circuit that drives the vibrator to detect an angular velocity signal, a circuit substrate that fixes the vibrator and components of the internal circuit and electrically connects the vibrator and the components, a cap that mechanically and electrically protects the vibrator and internal circuit fixed onto the circuit substrate. In the angular velocity sensor, an output signal processed by the internal circuit is taken out from an external terminal.

In this case, by measuring electrical properties of the finished angular velocity sensor using the external terminal thereof, the characteristics of the product are determined.

In general, an angular velocity sensor is subjected to various mechanical shocks, thermal stress, and other external forces in the manufacturing process before becoming a finished product, and thus, the characteristics of the vibrator thereof may vary. However, in known angular velocity sensors, the characteristics of the product are determined using the external terminal from which an output signal processed by the internal circuit is taken out, as described above, and therefore variations in characteristics of the vibrator itself cannot be directly detected.

For this reason, even if a micro-crack or other defect occurs in a vibrator in the process of manufacturing an angular velocity sensor, and thus, any characteristic of the vibrator itself varies, no significant variations occur in an output signal processed by the internal circuit in many cases. This disadvantageously makes it difficult to properly identify potentially defective products due to variations in characteristics of the vibrator.

### SUMMARY OF THE INVENTION

To overcome the problems described above, preferred embodiments of the present invention provide an angular velocity sensor in which a vibrator and an internal circuit are integrally provided on a circuit substrate and are arranged to detect minute variations in characteristics of the vibrator that cannot be detected from an output signal processed by the internal circuit after being assembled into a product so as to properly identify defective products, such as products including a vibrator having a micro-crack caused in the manufacturing process, so as to improve the reliability of the product.

An angular velocity sensor according to a preferred embodiment of the present invention includes a vibrator including a surface electrode, an internal circuit including an output electrode, the internal circuit driving the vibrator to detect an angular velocity signal, a circuit substrate including an external electrode arranged to output an angular velocity detection signal, the circuit substrate having the vibrator and components defining the internal circuit disposed thereon, and a cap mounted on the circuit substrate to cover a surface of the circuit substrate, the cap including the vibrator and the internal circuit disposed on the circuit substrate. The circuit substrate includes a vibrator inspection electrode arranged to detect a characteristic of the vibrator from outside after the vibrator and the internal circuit are covered by the cap. The surface electrode of the vibrator and the components defining the internal circuit are electrically connected to each other. The output electrode of the internal circuit and the external electrode of the circuit substrate are electrically connected to each other. The surface electrode of the vibrator and the vibrator inspection electrode are electrically connected to each other.

With a preferred embodiment of the present invention, the circuit substrate includes the vibrator inspection electrodes arranged to inspect the characteristics of the vibrators from the outside in addition to the external electrodes arranged to output an output signal processed by the internal circuit, and the surface electrodes of the vibrators and the vibrator inspection electrodes are electrically connected to each other. This allows direct measuring of the electrical characteristics of the vibrators, such as an impedance characteristic and a frequency characteristic, after the vibrators and internal circuit are disposed on the circuit substrate and then covered by the cap. Thus, minute variations in characteristics of the vibrators, which cannot be detected from a signal output from the internal circuit after being assembled into a product, are detected. As a result, defective products, such as products including a vibrator having a micro-crack caused in the manufacturing process, are correctly identified.

In the angular velocity sensor according to a preferred embodiment of the present invention, the vibrator inspection electrode may preferably be provided on a back surface of the circuit substrate in a location corresponding to the surface electrode of the vibrator. A barycentric location of the vibrator inspection electrode may preferably be substantially aligned with a barycentric location of the back surface of the circuit substrate after assembly.

With a preferred embodiment of the present invention, the vibrator inspection electrodes provided on the back surface of the circuit substrate in a location corresponding to the surface electrodes of the vibrators are preferably arranged such that the barycentric location of the vibrator inspection electrodes is substantially aligned with the barycentric location of the back surface of the circuit substrate after assembly. This prevents the occurrence of a turning moment that causes a turn of the circuit substrate when bringing an inspection probe in contact with the vibrator inspection electrodes in order to inspect the electrical characteristics of the vibrators after assembly. Thus, a contact failure of the inspection probe is prevented so that the measurement accuracy is further improved.

In the angular velocity sensor according to a preferred embodiment of the present invention, the vibrator inspection electrode and the external electrode may preferably both be provided on one surface of the circuit substrate.

With a preferred embodiment of the present invention, the vibrator inspection electrodes and the external electrodes are provided on one surface of the circuit substrate. Thus, inspection of the electrical characteristics of the vibrators using the vibrator inspection electrodes and determination of the characteristics of the product using the external electrodes can be simultaneously performed. As a result, highly reliable products are efficiently manufactured.

In the angular velocity sensor according to a preferred embodiment of the present invention, the barycentric location of the vibrator inspection electrode may preferably be substantially aligned with a barycentric location of the external electrode.

Thus, in a case where one of inspection of the electrical characteristics of the vibrators using the vibrator inspection electrodes and determination of the characteristics of the product using the external electrodes is performed and a case where inspection of the electrical characteristics of the vibrators using the vibrator inspection electrodes and determination of the characteristics of the product using the external electrode are simultaneously performed, the occurrence of a turning moment that causes a turn of the circuit substrate when bringing an inspection probe into contact with the vibrator inspection electrodes is prevented. This prevents a contact failure of the inspection probe, thereby further improving the measurement accuracy.

With a preferred embodiment of the present invention, in an angular velocity sensor in which vibrators and an internal circuit are integrally provided on a circuit substrate, minute variations in characteristics of the vibrators, which cannot be detected from a signal output from the internal circuit after assembled into a product, are effectively detected. Thus, defective products, such as products including a vibrator having a micro-crack, which occurs in the manufacturing process, are properly identified so that the reliability of products is improved.

The above-described advantages and other advantages of the present invention will be further clarified from the following description of preferred embodiments of the present invention with the reference to the accompanying drawings.

Other features, elements, steps, characteristics and advantages of the present invention will become more apparent from the following detailed description of preferred embodiments of the present invention, with reference to the attached drawings.

### BRIEF DESCRIPTION OF THE DRAWINGS

FIG. 1 is a drawing schematically showing an angular velocity sensor according to a preferred embodiment of the present invention.

FIG. 2 is an exploded view showing the angular velocity sensor according to a preferred embodiment of the present invention.

FIG. 3 is a drawing showing electrodes disposed on the back surface of a circuit substrate of the angular velocity sensor according to a preferred embodiment of the present invention.

FIG. 4 is a drawing schematically showing a structure of a tuning fork-type vibrator of the angular velocity sensor according to a preferred embodiment of the present invention.

FIG. 5 is a diagram showing a circuit configuration of the angular velocity sensor according to a preferred embodiment of the present invention.

FIG. 6 is a drawing showing the operating state of the fork tuning-type vibrator of the angular velocity sensor according to a preferred embodiment of the present invention.

FIG. 7 is a drawing showing the operating state of the fork tuning-type vibrator of the angular velocity sensor according to a preferred embodiment of the present invention at the time when an angular velocity is detected.

FIG. 8 is a drawing showing a vibrator inspection electrode provided for the angular velocity sensor according to a preferred embodiment of the present invention.

### DETAILED DESCRIPTION OF PREFERRED EMBODIMENT

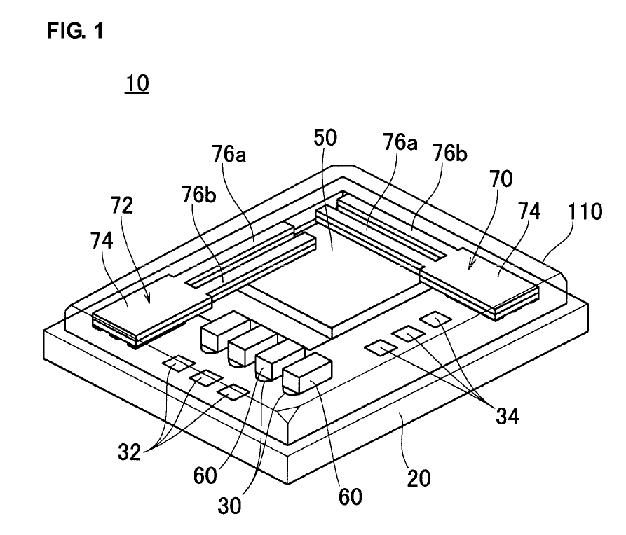

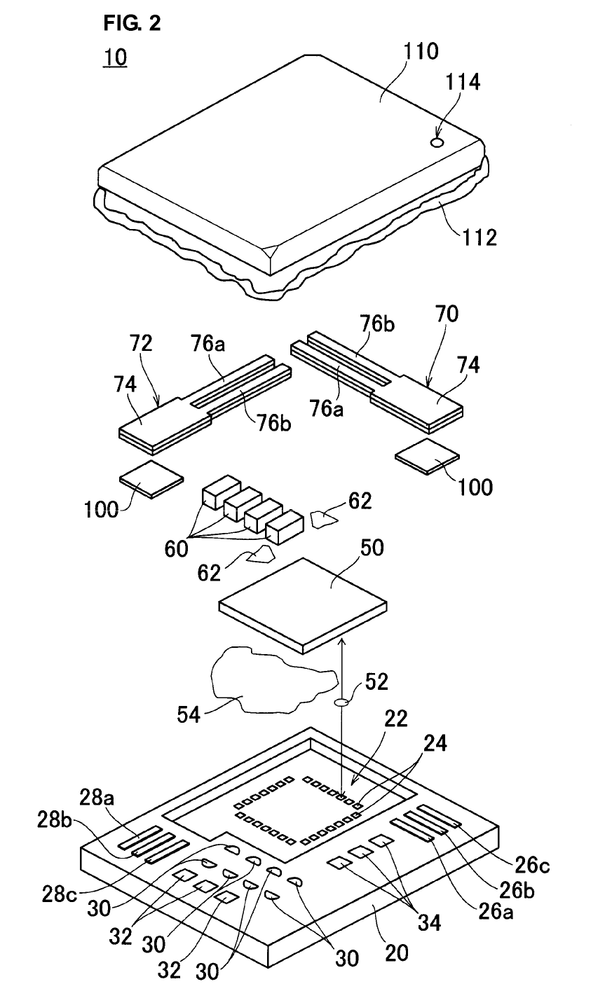

FIG. 1 is an internal perspective view showing an example of an angular velocity sensor according to a preferred embodiment of the present invention and FIG. 2 is an exploded perspective view thereof. An angular velocity sensor 10 includes a circuit substrate 20. The circuit substrate 20 is preferably configured in the shape of, for example, a rectangular or substantially rectangular plate. The circuit substrate 20 has a recess 22 on a first surface thereof. The recess 22 is disposed, for example, in a location close to one corner of the circuit substrate 20. In FIG. 2, the recess 22 preferably has a shape of a hook, for example. However, it may have any suitable shape as long as the shape is one in which an IC to be described later can be mounted. For example, the recess 22 may have a square or substantially square shape.

In the recess 22 of the circuit substrate 20, a plurality of electrodes 24 are preferably arranged in a square or substantially square configuration, for example. Outside the recess 22 of the circuit substrate 20 and near a short side of the circuit substrate 20 close to the recess 22, three rectangular or substantially rectangular electrodes 26a, 26b, and 26c are arranged side by side. The electrodes 26a to 26c are arranged so that the longitudinal direction thereof is the same or substantially the same as the direction of the short side of the circuit substrate 20 close to the recess 22. Outside the recess 22 of the circuit substrate 20 and near a long side of the circuit substrate 20 close to the recess 22, three rectangular or substantially rectangular electrodes 28a, 28b, and 28c are arranged side by side. The electrodes 28a to 28c are arranged so that the longitudinal direction thereof is the same or substantially the same as the direction of the long side of the circuit substrate 20 close to the recess 22.

Between the recess 22 and a short side of the circuit substrate 20 remote from the recess 22, a plurality of pairs of counter electrodes 30 are provided. Each pair of counter electrodes 30 are opposed to each other in the longitudinal direction of the circuit substrate 20. Also, the plurality of pairs of counter electrodes 30 are arranged along a short side of the circuit substrate 20. Between the counter electrodes 30 and the short side of the circuit substrate 20, a plurality of electrodes 32 are provided. Also, a plurality of electrodes 34 are provided near the electrodes 26a to 26c disposed near the short side of the circuit substrate 20 close to the recess 22. The electrodes 34 are disposed along the long side of the circuit substrate 20 remote from the recess 22.

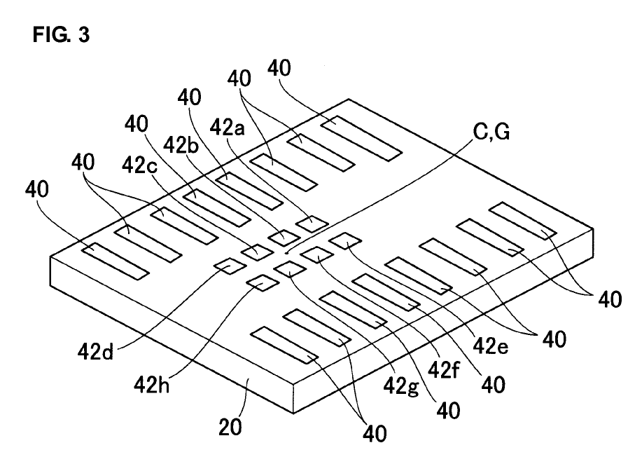

On a second surface of the circuit substrate 20, as shown in FIG. 3, a plurality of external electrodes 40 and eight inspection electrodes 42a to 42h, for example, are provided. The external electrodes 40 are arranged side by side along the opposed long sides of the circuit substrate 20. The inspection electrodes 42a to 42h are arranged side by side inside the external electrodes 40. Four inspection electrodes 42a to 42d and four inspection electrodes 42e to 42h, for example, are arranged along the corresponding long sides of the circuit substrate 20. A center point (barycenter location) C of the eight inspection electrodes 42a to 42h is disposed on the second surface of the circuit substrate 20 so that the center point C corresponds to a position G corresponding to the barycenter of the entire angular velocity sensor 10.

The circuit substrate 20 is preferably made of, for example, alumina. The electrodes 24, 26a to 26c, 28a to 28c, 30, 32, 34, 40, 42a to 42h provided on the circuit substrate 20 are preferably formed, for example, by plating electrodes made of tungsten with nickel and then gold. The circuit substrate 20 preferably has many conductive wiring members (not shown), such as via holes and patterns, for example.

An IC 50 is disposed in the recess 22 of the circuit substrate 20. The IC 50 is used to drive tuning fork-type vibrators to be described later and to process signals output from the tuning fork-type vibrators. The IC 50 has multiple external electrodes (not shown), which are connected to the electrodes 24 in the recess 22. In this case, for example, gold bumps 52 are preferably provided on the electrodes 24, and the electrodes 24 are connected to the external electrodes of the IC 50 via the gold bumps 52. Also, the IC 50 is fixed on the circuit substrate 20 using underfill 54 preferably made of an epoxy adhesive or other suitable adhesive, for example.

Chip capacitors 60 are connected to the pairs of counter electrodes 30 provided on the circuit substrate 20. As the chip capacitors 60, multilayer ceramic capacitors, for example, are preferably used, and external electrodes provided on both ends thereof are connected to the corresponding counter electrodes 30 preferably using pieces of solder 62, for example.

A first fork tuning-type vibrator 70 and a second fork tuning-type vibrator 72 are attached to the electrodes 26a to 26c and electrodes 28a to 28c, respectively, arranged outside the recess 22. Preferably, the first fork tuning-type vibrator 70 and second fork tuning-type vibrator 72 each include an approximately rectangular base 74, and two legs 76a and 76b extend from one edge in the longitudinal direction of the base. The legs 76a and 76b extend in parallel or substantially in parallel inside both edges in the width direction of the base 74.

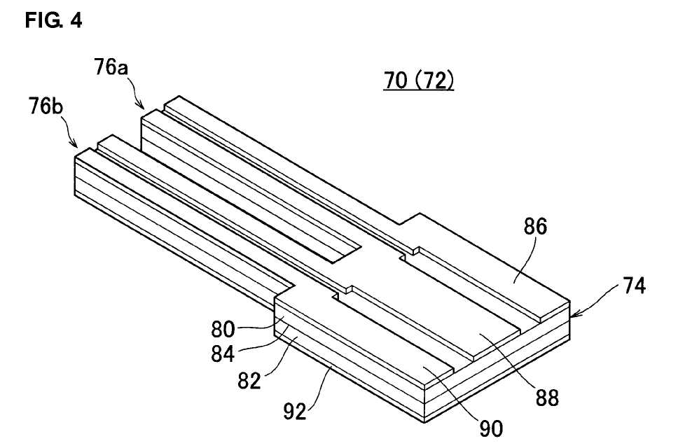

As shown in FIG. 4, the first fork tuning-type vibrator 70 and second fork tuning-type vibrator 72 each preferably include two fork tuning-type piezoelectric substrates 80 and 82, and an intermediate electrode 84 is interposed between the piezoelectric substrates 80 and 82. The piezoelectric substrates 80 and 82 are preferably made of a piezoelectric material such as lead zirconate titanate (PZT) and are polarized, for example, in opposite thickness directions.

The piezoelectric substrate 80 includes three surface electrodes 86, 88, and 90 on a surface thereof. The surface electrodes 86 and 88 are separated from each other in the approximate center in the width direction of the leg 76a, and the surface electrode 86 located at an edge extends from the base 74 to the leg 76a. The surface electrodes 88 and 90 are separated from each other in the approximate center in the width direction of the leg 76b, and the surface electrode 90 located at an edge extends from the base 74 to the leg 76b. The surface electrode 88 located in the approximate center extends from the base 74 to the legs 76b and 76b. The separation width between the surface electrodes 86 and 88 and that between the surface electrodes 88 and 90 are preferably both wider on the base 74 and narrower on the leg 76a or leg 76b. The piezoelectric substrate 82 includes an electrode 92 on substantially the entire surface thereof.

The first fork tuning-type vibrator 70 and second fork tuning-type vibrator 72 are attached to the electrodes 26a to 26c and electrodes 28a to 28c, respectively, arranged outside the recess 22 of the circuit substrate 20. The respective surface electrodes 86, 88, and 90 of the two tuning fork-type vibrators 70 and 72 are connected to the electrodes 26a, 26b, and 26c and electrodes 28a, 28b, and 28c, respectively, using a bonding material 100. As the bonding material 100, for example, an anisotropic, conductive adhesive, a conductive adhesive, a resin-metal composite material, gold bumps, is preferably used. Nonconductivity among the surface electrodes 86, 88, and 90 must be ensured. Therefore, if an anisotropic, conductive adhesive or a resin-gold composite material is used as the bonding material 100, the bonding material 100 may be provided on substantially the entire surface of the base 74 on which the three surface electrodes 86, 88, and 90 are provided. On the other hand, if other materials are used as the bonding material 100, it is necessary to divide the bonding material 100 into the respective sizes of the surface electrodes 86, 88, and 90 and then provide the divided bonding material 100 on the corresponding surface electrodes.

The first fork tuning-type vibrator 70 and second fork tuning-type vibrator 72 are preferably arranged in approximately perpendicular directions and have different resonant frequencies so as to prevent vibrations from each vibrator from affecting the other vibrator. The legs 76a and 76b of the first fork tuning-type vibrator 70 are preferably longer than those of the second fork tuning-type vibrator 72. Thus, the first fork tuning-type vibrator 70 has a resonant frequency lower than that of the second fork tuning-type vibrator 72.

The first fork tuning-type vibrator 70 having the lower resonant frequency is connected to the electrodes 26a to 26c arranged near the short side of the circuit substrate 20. The second fork tuning-type vibrator 72 having the higher resonant frequency is connected to the electrodes 28a to 28c arranged near the long side of the circuit substrate 20. The respective legs 76a and 76b of the first fork tuning-type vibrator 70 and second fork tuning-type vibrator 72 extend toward the recess 22 along the short side or long side of the circuit substrate 20.

A circuit defined by the IC 50, chip capacitors 60, and other circuit elements are connected to the external electrodes 40 provided on the second surface of the circuit substrate 20 via the electrodes 24, counter electrodes 30 and wiring members (not shown). The respective surface electrodes 86, 88, and 90 of the first fork tuning-type vibrator 70 and second fork tuning-type vibrator 72 are connected to a circuit of the IC 50 via the electrodes 26a to 26c or electrodes 28a to 28c, and wiring members (not shown), and are connected to the inspection electrodes 42a to 42h provided on the second surface of the circuit substrate 20. In this case, the surface electrodes 86, 88, and 90 of the first fork tuning-type vibrator 70 and those of the second fork tuning-type vibrator 72 are connected to the four inspection electrodes 42a to 42d and the other four inspection electrodes 42e to 42h, respectively, which are disposed in two lines.

The surface electrode 88 located in the center of the first fork tuning-type vibrator 70 is connected to the two outer inspection electrodes 42a and 42d among the four inspection electrodes 42a to 42d arranged side by side; the surface electrodes 86 and 90 located at both edges of the first fork tuning-type vibrator 70 are connected to the inner two inspection electrodes 42b to 42c thereamong. Also, the surface electrode 88 located in the approximate center of the second fork tuning-type vibrator 72 is connected to the two outer inspection electrodes 42e and 42h among the four inspection electrodes 42e to 42h arranged side by side, the surface electrodes 86 and 90 located at both edges of the second fork tuning-type vibrator 72 are connected to the inner two inspection electrodes 42f and 42g thereamong.

A cap 110 is mounted on the first surface of the circuit substrate 20 such that the cap covers the IC 50, chip capacitors 60, first fork tuning-type vibrator 70, and second fork tuning-type vibrator 72. The cap 110 is preferably made of a material such as alumina or German silver, for example, and preferably has a shape of a substantially rectangular container which corresponds to the shape of the circuit substrate 20.

In order to mount the cap 110 on the circuit substrate 20, a cap adhesive 112 is preferably provided between the edges of the cap 110 and the circuit substrate 20. If the insulative cap 110 made of, e.g., alumina is mounted, an epoxy adhesive, for example, is preferably used as the cap adhesive 112. If the conductive cap 110 made of German silver is mounted, an epoxy adhesive or an epoxy conductive adhesive, for example, is preferably used as the cap adhesive 112.

The cap 110 has a through hole 114 to protect against explosions. The through hole 114 is provided near a corner of the cap 110 in a location corresponding to the base 74 of the first fork tuning-type vibrator 70. The through hole 114 may be formed near a corner of the cap 110 in a position corresponding to the base 74 of the second fork tuning-type vibrator 72. That is, it is preferable to form the through hole 114 in a location at which the through hole 114 would not be disposed over the IC 50 even if the cap 110 is rotated by 180° and then mounted on the circuit substrate 20.

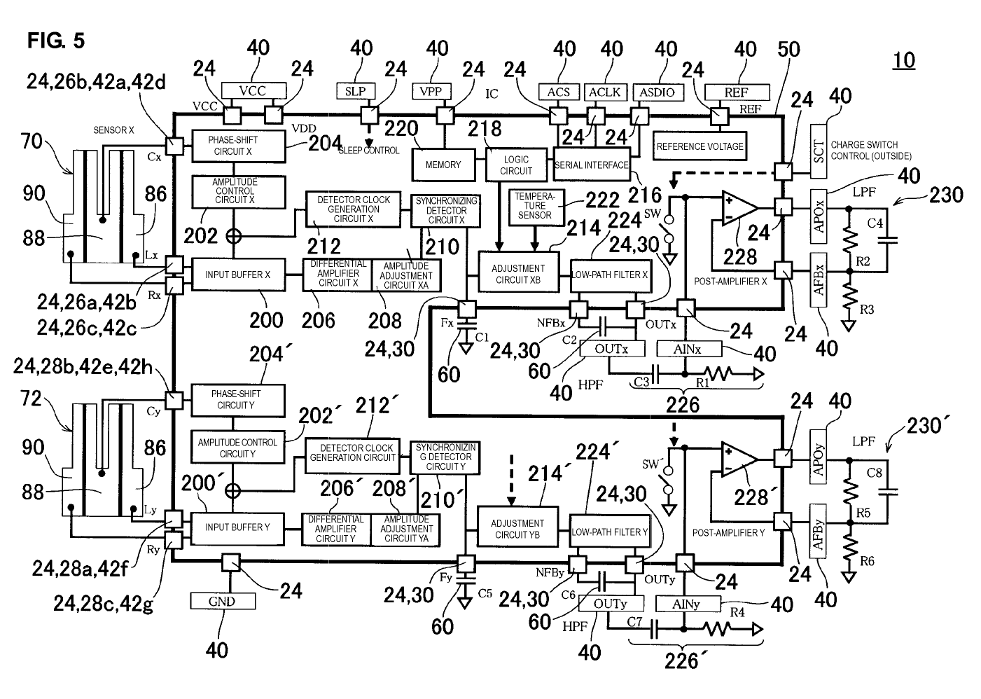

Next, a circuit configuration of the angular velocity sensor 10 will be described with reference to FIG. 5. In the angular velocity sensor 10, a circuit configuration associated with the first fork tuning-type vibrator 70 and one associated with the second fork tuning-type vibrator 72 are substantially the same as each other. Therefore, first, the circuit configuration associated with the first fork tuning-type vibrator 70 will be described in detail and then that associated with the second fork tuning-type vibrator 72 will be briefly described.

In the angular velocity sensor 10, the surface electrodes 86 and 90 of the first fork tuning-type vibrator 70 are connected to two input terminals of an input buffer 200 included in the IC 50 via the electrodes 24, 26a, and 26c, and wiring members (not shown). The input buffer 200 includes one first output terminal and two second output terminals. The first output terminal is used to output a signal that is the sum of signals input to the two input terminals. The second two output terminals are used to output signals input to the two input terminals. In the IC 50, the first output terminal of the input buffer 200 is connected to an input terminal of an amplitude control circuit 202 to control the amplitude of a signal. An output terminal of the amplitude control circuit 202 is connected to an input terminal of a phase-shift circuit 204 to correct the phase of a signal. An output terminal of the phase-shift circuit 204 in the IC 50 is connected to the surface electrode 88 of the first fork tuning-type vibrator 70 via the electrodes 24 and 26b, and wiring members (not shown). Thus, a drive feedback loop is provided in the first fork tuning-type vibrator 70. As described above, the surface electrodes 86, 88, and 90 of the first fork tuning-type vibrator 70 are connected to the four corresponding inspection electrodes 42a to 42d.

In the IC 50, the two second output terminals of the input buffer 200 are connected to two input terminals of a differential amplifier circuit 206. An output terminal of the differential amplifier circuit 206 is connected to a first input terminal of a synchronizing detector circuit 210 via an amplitude adjustment circuit 208. Also, the first output terminal of the input buffer 200 is connected to a second input terminal of the synchronizing detector circuit 210 via a detection clock generation circuit 212. The synchronizing detector circuit 210 is arranged to detect a signal input to a first input terminal thereof in synchronization with a signal (detection clock) input to a second input terminal thereof. An output terminal of the synchronizing detector circuit 210 is connected to one external electrode (electrode 24) of the IC 50. A capacitor C1 (chip capacitor 60) is connected between this external electrode and another external electrode (another electrode 24, external electrode 40 (REF)) of the IC 50 to which a reference voltage is to be applied, via a counter electrode 30 and a wiring member (not shown).

In addition, in the IC 50, the output terminal of the synchronizing detector circuit 210 is connected to one input terminal of an adjustment circuit 214. The adjustment circuit 214 is arranged to compensate for a variation due to a temperature variation in a signal output from the synchronizing detector circuit 210. For this reason, the IC 50 includes a serial interface 216, a logic circuit 218, a memory 220, and a temperature sensor 222. Three input terminals of the serial interface 216 are connected to three external electrodes (three electrodes 24) and three external electrodes 40 (ACS, ACLK, and ASDIO). An output terminal of the serial interface 216 is connected to an input terminal of the logic circuit 218. An output/input terminal of the logic circuit 218 is connected to an output/input terminal of the memory 220. A VPP voltage terminal of the memory 220 is connected to an external electrode (electrode 24) of the IC 50 and an external electrode 40 (VPP). Thus, various types of data, such as data related to actually measured variations in impedance characteristic of the first fork tuning-type vibrator 70 due to temperature variations, can be stored from the external electrode 40 into the memory 220 via the serial interface 216 and logic circuit 218. An output terminal of the logic circuit 218 is connected to another input terminal of the adjustment circuit 214. Thus, data stored in the memory 220 can be provided to the adjustment circuit 214 via the logic circuit 218. An output terminal of the temperature sensor 222 is connected to yet another input terminal of the adjustment circuit 214. Thus, the adjustment circuit 214 can compensate for a variation due to a temperature variation in a signal input thereinto, that is, a signal output from the synchronizing detector circuit 210 based on data stored in the memory 220 and a signal output from the temperature sensor 222.

Although not shown, the memory 220 is also connected to the above-mentioned amplitude adjustment circuit 208. This allows the amplitude adjustment circuit 208 to adjust the amplitude of a signal output from the differential amplifier circuit 206 based on data related to a gain stored in the memory 220.

In the IC 50, an output terminal of the adjustment circuit 214 is connected to an input terminal of a low-path filter 224. The low-path filter 224 is arranged to pass angular velocity signals having frequencies in a low frequency band, for example, including about 10 Hz to about 50 Hz, among angular velocity signals detected by the angular velocity sensor. A first output terminal of the low-path filter 224 is connected to an external electrode (electrode 24) of the IC 50, an electrode 30, and an external electrode 40 (OUTx). The low-path filter 224 has a second output terminal arranged to pass and output an input signal, and the second output terminal is connected to another external electrode (electrode 24) of the IC 50 and another electrode 30. A capacitor C2 (chip capacitor 60) is connected between the first and second output terminals of the low-path filter 224 (between the electrodes 30).

The first output terminal of the low-path filter 224, that is, the external electrode 40 (OUTx) is connected to an input terminal of an externally provided high-pass filter 226. The high-pass filter 226 is arranged to cut off a direct-current component of a signal. The high-pass filter 226 includes a capacitor C3 and a resistor R1. The capacitor C3 is connected between an input terminal of the high-pass filter 226 and an output terminal thereof. The resistor R1 is connected between the output terminal of the high-pass filter 226 and another external electrode 40 (REF) to which a reference voltage of the IC 50 is to be applied.

An output terminal of the high-pass filter 226, that is, the contact between the capacitor C3 and resistor R1 is connected to an external electrode 40 (AINx). The external electrode 40 (AINx) is connected to a positive input terminal of an operational amplifier 228 used in a first post-amplifier of the IC 50 via an electrode 24. The first post-amplifier is preferably arranged to amplify the amplitude of a signal input into the external electrode 40 (AINx), for example, about fifty times. A negative input terminal of the operational amplifier 228 is preferably connected to an external electrode 40 (AFBx) via an electrode 24, and an output terminal thereof is preferably connected to another external electrode 40 (APOx) via another electrode 24. An externally provided low-pass filter 230 is connected to the external electrodes 40 (AFBx, APOx). The low-pass filter 230 includes a resistor R2 and a capacitor C4. The resistor R2 and capacitor C4 are connected in parallel between the external electrodes 40 (AFBx, APOx). Also, a resistor R3 is connected between the external electrode 40 (AFBx) and another external electrode 40 (REF) to which a referenced voltage is to be applied. This allows the first post-amplifier including the operational amplifier 228 to amplify the amplitude of a signal input into the external electrode 40 (AINx), for example, about fifty times and to output the resultant signal from the output terminal of the operational amplifier 228, that is, the external electrode 40 (APOx).

In addition, the IC 50 includes a switch SW. The switch SW is connected between an external electrode (electrode 24) of the IC 50 connected to the external electrode 40 (AINx) and another electrode (another electrode 24) of the IC 50 connected to another external electrode 40 (REF) to which a reference voltage of the IC 50 is to be applied. Also, the switch SW is connected to an external electrode (electrode 24) of the IC 50 connected to an external electrode 40 (SCT). The switch SW is turned on or off in accordance with a control signal input to the external electrode 40 (SCT). If the capacitor C3 of the high-pass filter 226 is charged by activating the switch SW, e.g., for about 0.2 sec., a signal from the output terminal of the low-path filter 224, that is, the external electrode 40 (OUTx) is transmitted to the positive input terminal of the operational amplifier 228 within a short time. This allows shortening of the rising time of an output signal at the output terminal of the operational amplifier 228, that is, external electrode 40 (APOx).

The external electrode 40 (VCC) is connected to electrodes 24 connected to the VCC and VDD of the IC 50 via wiring members (not shown), and an external electrode 40 (GND) is connected to an electrode 24 connected to a GND of the IC 50 via a wring member (not shown). Also, an external electrode 40 (SLP) is connected to an electrode 24 connected to a sleep control terminal of the IC 50 via a wiring member (not shown).

In the angular velocity sensor 10, as with the first fork tuning-type vibrator 70, the surface electrodes 86 and 90 of the second fork tuning-type vibrator 72 are connected to two input terminals of an input buffer 200′, which is substantially equivalent to the input buffer 200, included in the IC 50 via electrodes 24, 28a, and 28c and wiring members (not shown). A first output terminal of the input buffer 200′ is connected to the surface electrode 88 of the second fork tuning-type vibrator 72 via an amplitude control circuit 202′, which is substantially equivalent to the amplitude control circuit 202, a phase-shift circuit 204′, which is substantially equivalent to the phase-shift circuit 204, electrodes 24 and 28b, and wiring members (not shown). Thus, a drive feedback loop is provided in the second fork tuning-type vibrator 72. Note that this drive feedback loop is configured such that the drive frequency of the second fork tuning-type vibrator 72 is higher than that of the first fork tuning-type vibrator 70.

Two second output terminals of the input buffer 200′ are also connected to a first input terminal of a synchronizing detector circuit 210′, which is substantially equivalent to the synchronizing detector circuit 210, via a differential amplifier circuit 206′, which is substantially equivalent to the differential amplifier circuit 206, and an amplitude adjustment circuit 208′, which is substantially equivalent to the amplitude adjustment circuit 208. Also, the first output terminal of the input buffer 200′ is connected to a second input terminal of the synchronizing detector circuit 210′ via a detection clock generation circuit 212, which is substantially equivalent to the detection clock generation circuit 212. Although not shown, the memory 220 is also connected to the amplitude adjustment circuit 208′. This allows the amplitude adjustment circuit 208′ to adjust the amplitude of a signal output from the differential amplifier circuit 206′ based on data related to a gain stored in the memory 220. Also, the detection clock generation circuit 212′ generates a detection clock having a shorter cycle than that of the detection clock generation circuit 212 in accordance with the higher drive frequency of the second fork tuning-type vibrator 72. The cycle of detection of the synchronizing detector circuit 210′ is also shorter than that of the synchronizing detector circuit 210.

The output terminal of the synchronizing detector circuit 210′ is connected to one external electrode (electrode 24) of the IC 50 and an electrode 30. A capacitor C5 (chip capacitor 60) is connected between the electrode 30 and another external electrode (another electrode 24, external electrode 40 (REF)) of the IC 50 to which a reference voltage is to be applied.

Further, in the IC 50, the output terminal of the synchronizing detector circuit 210′ is connected to one input terminal of an adjustment circuit 214′, which is substantially equivalent to the adjustment circuit 214. Also, the memory 220 and temperature sensor 222 are connected to another input terminal and yet another input terminal, respectively, of the adjustment circuit 214′. Thus, data stored in the memory 220 can be provided to the adjustment circuit 214′. Also, the adjustment circuit 214′ can effectively compensate for a variation due to a temperature variation in a signal output from the synchronizing detector circuit 210′ based on data related to the second fork tuning-type vibrator 72 stored in the memory 220 and a signal output from the temperature sensor 222.

In the IC 50, an output terminal of the adjustment circuit 214′ is connected to an input terminal of a low-path filter 224′, which is substantially equivalent to the low-path filter 224. A first output terminal of the low-path filter 224′ is connected to an external electrode (electrode 24) of the IC 50, an electrode 30, and an external electrode 40 (OUTy). A second output terminal of the low-path filter 224′ is connected to another external electrode (electrode 24) of the IC 50 and another electrode 30. A capacitor C6 (chip capacitor 60) is connected between the first and second output terminals of the low-path filter 224′ (between the electrodes 30).

The output terminal of the low-path filter 224′, that is, the external electrode 40 (OUTy) is connected to an input terminal of an externally provided high-pass filter 226′, which is substantially equivalent to the high-pass filter 226. A capacitor C7 is connected between an input terminal and an output terminal of the high-pass filter 226′. A resistor R4 is connected between the output terminal of the high-pass filter 226 and another external electrode 40 (REF) to which a reference voltage of the IC 50 is to be applied.

The output terminal of the high-pass filter 226′, that is, the contact between the capacitor C7 and resistor R4 is connected to an external electrode 40 (AINy). The external electrode 40 (AINy) is preferably connected to a positive input terminal of an operational amplifier 228′ in a second post-amplifier, which is substantially equivalent to the first post-amplifier, of the IC 50 via an electrode 24, for example. The second post-amplifier is arranged to amplify the amplitude of a signal input into the external electrode 40 (AINy) preferably, for example, about fifty times. A negative input terminal of the operational amplifier 228′ is preferably connected to an external electrode 40 (AFBy) via an electrode 24, for example, and an output terminal thereof is preferably connected to another external electrode 40 (APOy) via another electrode 24, for example. An externally provided low-pass filter 230′, which is substantially equivalent to the low-pass filter 230, is connected to the external electrodes 40 (AFBy, APOy). A resistor R5 and a capacitor C8 of the low-pass filter 230′ are connected in parallel between the external electrodes 40 (AFBy, APOy). Also, a resistor R6 is connected between the external electrode 40 (AFBy) and another external electrode 40 (REF) to which a referenced voltage is to be applied. This allows the second post-amplifier including the operational amplifier 228′ to amplify the amplitude of a signal input into the external electrode 40 (AINy) preferably, for example, about fifty times and to output the resultant signal from the output terminal of the operational amplifier 228′, that is, the external electrode 40 (APOy).

Further, the IC 50 includes a switch SW′, which is substantially equivalent to the switch SW. The switch SW′ is connected between an external electrode (electrode 24) of the IC 50 connected to the external electrode 40 (AINy) and another external electrode (another electrode 24) of the IC 50 connected to another external electrode 40 (REF) to which a reference voltage of the IC 50 is to be applied. The switch SW′ is also connected to an external electrode (electrode 24) of the IC 50 and the external electrode 40 (SCT). The switch SW′ is also turned on or off by a control signal input to the external electrode 40 (SCT). Thus, if the capacitor C7 of the high-pass filter 226′ is charged by activating the switch SW′, e.g., for about 0.2 sec., an signal from the output terminal of the low-path filter 224′, that is, the external electrode 40 (OUTy) is transmitted to the positive input terminal of the operational amplifier 228′ within a short time. This allows shortening of the rising time of an output signal at the output terminal of the operational amplifier 228′, that is, the external electrode 40 (APOy).

Next, the operating state of the angular velocity sensor 10 will be described. In the angular velocity sensor 10, for example, the first fork tuning-type vibrator 70 is preferably used to detect a rotation angular velocity applied using, as the approximate center, the X axis parallel with the short sides of the circuit substrate 20 and the second fork tuning-type vibrator 72 is used to detect a rotation angular velocity applied using, as the approximate center, the Y axis extending parallel or substantially parallel to the long sides of the circuit substrate 20.

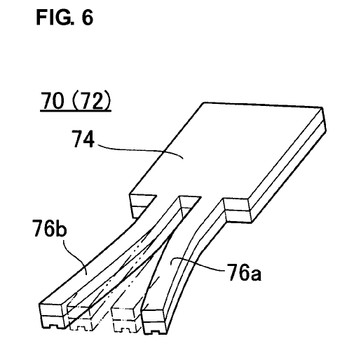

In the first fork tuning-type vibrator 70, a self-excitation drive circuit is defined by the drive feedback loop including the input buffer 200, amplitude control circuit 202, and phase-shift circuit 204. For example, as shown in FIG. 6, the legs 76a and 76b make basic vibrations such that the legs are both opened or closed. In a state in which the legs 76a and 76b are both opened (in a state shown by a solid line in FIG. 6), a portion of the first fork tuning-type vibrator 70 having the surface electrode 88 located in the approximate center expand and portions thereof having the surface electrodes 86 and 90 located at both edges shrink. Conversely, in a state in which the legs 76a and 76b are both closed, the portion of the first fork tuning-type vibrator 70 having the surface electrode 88 located in the approximate center shrinks and the portions thereof having the surface electrodes 86 and 90 expand. When such basic vibrations are made, the two legs 76a and 76b vibrate symmetrically in the same state with respect to the polarization directions. Therefore, the same signals are output from the surface electrodes 86 and 90 located at both edges. Thus, a signal “0” is output from the differential amplifier circuit 206 dedicated to a detection circuit and in turn from the external electrode 40 (APOx).

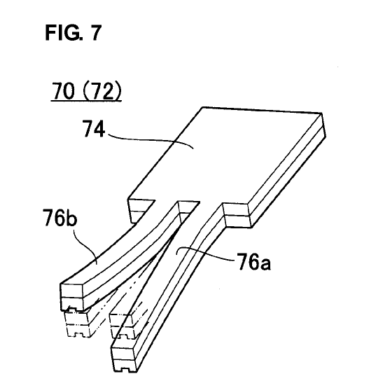

When a rotation angular velocity using the X axis as the approximate center is applied to the first fork tuning-type vibrator 70 in this basic vibration state, a Coriolis force is applied to the legs 76a and 76b in a direction perpendicular or substantially perpendicular to the direction of the basic vibrations. The Coriolis force acting on the leg 76a and that acting on the leg 76b are directed in opposite directions. Therefore, the legs 76a and 76b are displaced in the opposite directions, for example, as shown in FIG. 7. Such displacements cause the surface electrodes 86 and 90 located at both edges to output signals having opposite phases, and cause the differential amplifier circuit 206 to output a large signal corresponding to the rotation angular velocity. The magnitude and polarity of the signals output in this manner correspond to the magnitude of the rotation angular velocity and the rotation direction, respectively.

The amplitude of a signal output from the differential amplifier circuit 206 is adjusted by the amplitude adjustment circuit 208 based on data stored in the memory 220. The amplitude-adjusted signal is detected by the synchronizing detector circuit 210 in synchronization with a detection clock from the detection clock generation circuit 212. A variation due to a temperature variation in the detected signal is compensated for by the adjustment circuit 214. If the frequency of the temperature-compensated signal falls within a required low frequency range, the signal is passed through the low-path filter 224. Further, a direct-current component of the signal is cut off by the high-pass filter 226. Subsequently, the direct-current-cut-off signal is amplified by the first post-amplifier including the operational amplifier 228 and output from the output terminal of the operational amplifier 228, that is, the external electrode 40 (APPx). In this manner, the magnitude and rotation direction of the rotation angular velocity applied with the X axis as the approximate center are detected using the magnitude and polarity of the signal output from the external electrode 40 (APOx).

As in the first fork tuning-type vibrator 70, in the second fork tuning-type vibrator 72, the legs 76a and 76b make basic vibrations based on the drive feedback loop including input buffer 200′. Note that, in the second fork tuning-type vibrator 72, the directions of the basic vibrations of the legs 76a and 76b are changed in accordance with a rotation angular velocity applied with the Y axis as the approximate center. Therefore, for the second fork tuning-type vibrator 72, the magnitude and rotation direction of the rotation angular velocity applied with the Y axis as the approximate center are detected using the magnitude and polarity of a signal output from the differential amplifier circuit 206′ and in turn from the external electrode 40 (APOy).

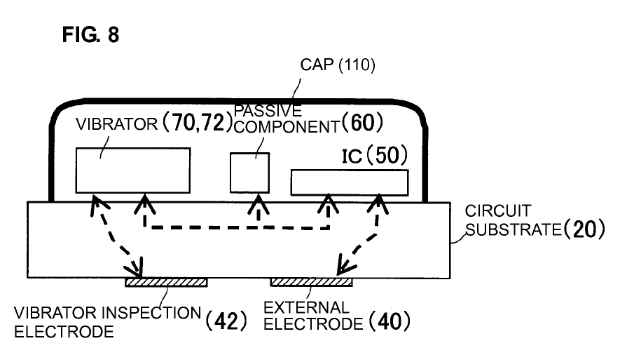

As shown in FIG. 8, the angular velocity sensor 10 according to the above-mentioned preferred embodiment of the present invention is an angular velocity sensor obtained by fixing the two fork tuning-type vibrators 70 and 72, and the IC 50 and passive component 60 included in the internal circuit arranged to drive the vibrators to detect an angular velocity signal, on the circuit substrate 20 and then covering the IC 50, passive component 60, and other components using the cap 110. The surface electrodes of the fork tuning-type vibrators 70 and 72 are electrically connected to the IC 50 and passive component 60 in the circuit substrate. A signal output from the internal circuit is output from the external electrode 40 that is provided on the back surface of the circuit substrate and electrically connected to the internal circuit. Also, the inspection electrodes 42 arranged to inspect the electrical characteristics of the vibrators are provided on the back surface of the circuit substrate 20, and the surface electrodes of the fork tuning-type vibrators 70 and 72 are electrically connected to the inspection electrodes 42 without passing through the IC 50 or passive component 60. This allows direct measuring of the electrical characteristics of the fork tuning-type vibrators, such as an impedance characteristic and a frequency characteristic, after being assembled into a product.

Also, the inspection electrodes 42 are provided on the back surface of the circuit substrate 20 and sealed by the cap 110 in an arrangement corresponding to the surface electrodes of the fork tuning-type vibrators. The barycentric location of the inspection electrodes 42 are preferably arranged to correspond to the barycentric location of the back surface of the circuit substrate including the IC 50, passive component 60, and other components after assembled into the angular velocity sensor 10. This prevents a turning moment that causes a turn of the circuit substrate from occurring when bringing an inspection probe into contact with the vibrator inspection electrodes in order to inspect the electrical characteristics of the vibrators after the assembly. Thus, a contact failure of the inspection probe is prevented so that the accuracy of measurement of the electrical characteristics of the vibrators is further improved.

In the above-mentioned preferred embodiment, the barycentric location of the vibrator inspection electrodes preferably corresponds to the barycentric location of the back surface of the circuit substrate after assembly. However, the former barycentric location does not necessarily need to correspond to the latter barycentric location and may be disposed near the latter barycentric location unless the accuracy of measurement of the electrical characteristics of the vibrators is adversely affected.

Also, the external electrodes and the vibrator inspection electrodes may be arranged so that the barycentric location of both the external electrodes and the vibrator inspection electrodes is substantially aligned with the barycentric location of the back surface of the circuit substrate after assembly. Thus, when simultaneously performing inspection of the electrical characteristics of the vibrators using the vibrator inspection electrodes and determining of the characteristics of the product using the external electrodes, the occurrence of a contact failure of the inspection probe is prevented so that the measurement accuracy is further improved.

In the above-mentioned preferred embodiment, both the vibrator inspection electrodes and external electrodes are preferably provided on the back surface of the circuit substrate. However, any or both of these types of electrodes may be provided in a location other than the back surface, such as a side surface of the circuit substrate.

While the cap has the shape of a substantially rectangular container in the above-mentioned preferred embodiment, the present invention is not limited thereto. For example, the circuit substrate may be configured in the shape of a container and may be covered with a plate-shaped cap.

While the two-axis angular velocity sensor using the two fork tuning-type vibrators is preferably used as an angular velocity sensor in the above-mentioned preferred embodiment, the present invention is not limited thereto. A single-axis angular velocity sensor using a single fork tuning-type vibrator or an angular velocity sensor using a vibrator other than a fork tuning-type vibrator may preferably be used, for example.

As described above, with preferred embodiments of the present invention, minute variations in characteristics of the vibrators, which cannot be detected from an output signal from the internal circuit after assembled into a product, can be effectively detected. Thus, defective products, such as ones including a vibrator having a micro-crack, caused in the manufacturing process are properly identified. As a result, a highly reliable angular velocity sensor is provided.

The present invention is not limited to the above-mentioned preferred embodiments. If the advantages of the present invention are achieved, the elements described in the preferred embodiments may be replaced as appropriate, new elements may be added, or some elements may be eliminated.

While the preferred embodiment of the invention has been described above, it is to be understood that variations and modifications will be apparent to those skilled in the art without departing from the scope and spirit of the present invention. The scope of the present invention, therefore, is to be determined solely by the following claims.

What is claimed is:

1. An angular velocity sensor comprising:
a vibrator including a surface electrode;
an internal circuit including an output electrode and being arranged to drive the vibrator to detect an angular velocity signal;
a circuit substrate including an external electrode arranged to output an angular velocity detection signal, the vibrator and the internal circuit being disposed on the circuit substrate; and
a cap mounted on the circuit substrate to cover a surface of the circuit substrate, the cap covering the vibrator and the internal circuit disposed on the circuit substrate; wherein
the circuit substrate includes a vibrator inspection electrode arranged to inspect a characteristic of the vibrator from outside the angular velocity sensor after the vibrator and the internal circuit are covered by the cap;
the surface electrode of the vibrator and the internal circuit are electrically connected to each other;
the output electrode of the internal circuit and the external electrode of the circuit substrate are electrically connected to each other; and
the surface electrode of the vibrator and the vibrator inspection electrode are electrically connected to each other.

2. The angular velocity sensor according to claim 1, wherein the vibrator inspection electrode is provided on a back surface of the circuit substrate and is arranged to correspond to a position of the surface electrode of the vibrator, and a barycentric location of the vibrator inspection electrode is substantially aligned with a barycentric location of the back surface of the circuit substrate after assembly.

3. The angular velocity sensor according to claim 1, wherein the vibrator inspection electrode and the external electrode are both provided on one surface of the circuit substrate.

4. The angular velocity sensor according to claim 2, wherein the barycentric location of the vibrator inspection electrode is substantially aligned with a barycentric location of the external electrode.
